(19) United States
(12) Patent Application Publication
(10) Pub. No.: US 2025/0275293 A1
(43) Pub. Date: Aug. 28, 2025

(54) SOLAR CELL

(71) Applicant: Sino-American Silicon Products Inc., Hsinchu City (TW)

(72) Inventors: TAI-CHAO KUO, Taipei City (TW); HONG-KAI YU, Yilan County (TW); MENG-YI LAI, Yilan County (TW)

(73) Assignee: Sino-American Silicon Products Inc., Hsinchu City (TW)

(21) Appl. No.: 18/585,309

(22) Filed: Feb. 23, 2024

(51) Int. Cl. H01L 31/0216

(52) U.S. Cl. CPC H10F 77/315

(57) ABSTRACT

A solar cell includes a substrate, a semiconductor layer, a passivation layer, a first protective layer, and a second protective layer, wherein the substrate has a front surface and a rear surface that are disposed oppositely; the semiconductor layer is disposed on the front surface; the passivation layer includes an AlOₓ (X>0) material; the first protective layer includes a SiOₓ (X>0) material; the second protective layer includes a SiNₓ (X>0) material; and the passivation layer, the first protective layer, and the second protective layer are sequentially disposed on the rear surface of the substrate and are disposed in a direction away from the rear surface.

### FIELD OF THE INVENTION

The present invention relates to solar cells, and in particular to a solar cell that can effectively suppress a potential induced degradation (PID) effect.

### BACKGROUND OF THE INVENTION

It is known that a potential-induced degradation effect that occurs during operation of a solar cell module reduces the power generation efficiency of the solar cell module, which in turn affects an overall power output of the solar cell module, and may even result in destruction of parts of the solar cell module.

The main reason for occurrence of a PID effect is that there is a leakage current between glass and packaging materials in the cell, so that short-circuit effects caused by a large number of charges and other free ions gathered on a surface of the solar cell deteriorate performance characteristics of the solar cell, such as causing a decrease in a cell fill factor, an open circuit voltage, a short circuit current, etc., and resulting in the overall performance and durability of the cell module to be lower than design expectations.

Therefore, one of the directions that the inventor is committed to researching and developing is how to provide a solar cell with an anti-PID effect to reduce or suppress occurrence of a PID effect, so as to achieve multiple efficiencies of improving the power generation efficiency and reducing the cost of packaging cell modules, etc.

### SUMMARY OF THE INVENTION

In view of the above, an objective of the present invention is to provide a solar cell that can reduce and suppress the PID effect.

In order to achieve the above objective, the present invention provides a solar cell including a substrate, a semiconductor layer, a passivation layer, a first protective layer, and a second protective layer, wherein the substrate has a front surface and a rear surface that are disposed oppositely; the semiconductor layer is disposed on the front surface; the passivation layer includes an AlOₓ (X>0) material; the first protective layer includes a SiOₓ (X>0) material; the second protective layer includes a SiNₓ (X>0) material; and the passivation layer, the first protective layer, and the second protective layer are sequentially disposed on the rear surface of the substrate and are disposed in a direction away from the rear surface.

The present invention has the effects that with the arrangement of the first protective layer, the PID effect can be effectively reduced and suppressed, and the purposes of improving the power generation efficiency and reducing the cost of packaging cell modules, etc. can be achieved.

### BRIEF DESCRIPTION OF THE DRAWINGS

FIG. 1 is a schematic diagram of a solar cell of a first preferred embodiment of the present invention.

FIG. 2 is a schematic diagram of a solar cell of a second preferred embodiment of the present invention.

FIG. 3 is a schematic diagram of a solar cell of a third preferred embodiment of the present invention.

### DETAILED DESCRIPTION OF PREFERRED EMBODIMENTS

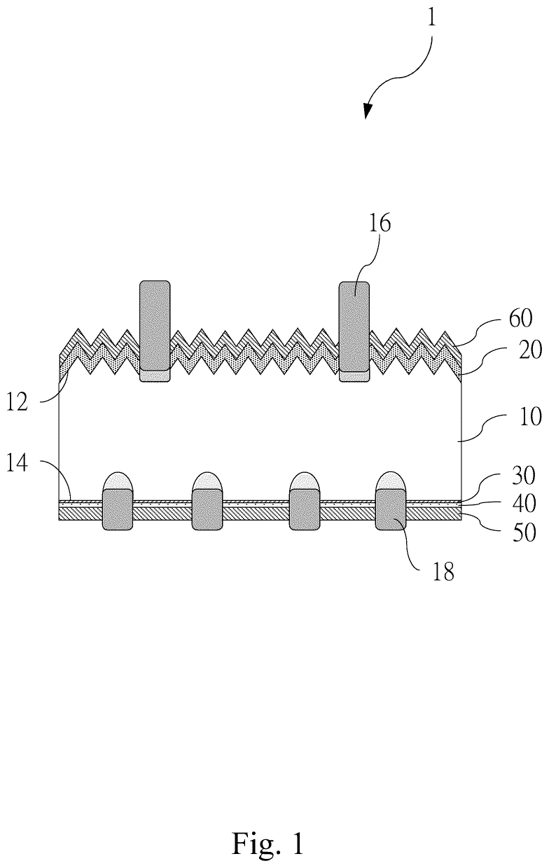

In order to illustrate the present invention more clearly, a preferred embodiment is hereby exemplified and described in detail in conjunction with the drawings as follows. Referring to FIG. 1, a solar cell 1 of a first preferred embodiment of the present invention is shown, including a substrate 10, a semiconductor layer 20, a passivation layer 30, a first protective layer 40, and a second protective layer 50, wherein the substrate 10 has a front surface 12 and a rear surface 14 that are disposed oppositely; the semiconductor layer 20 is disposed on the front surface 12; the passivation layer 30 includes an AlOₓ (X>0) material; the first protective layer 40 includes a SiOₓ (X>0) material; the second protective layer 50 includes a SiNₓ (X>0) material; and the passivation layer 30, the first protective layer 40, and the second protective layer 50 are sequentially disposed on the rear surface 14 of the substrate 10 and are disposed in a direction away from the rear surface 14. For example, the passivation layer 30, the first protective layer 40, and the second protective layer 50 can be sequentially stacked on the substrate through, for example, a plasma-enhanced chemical vapor deposition (PECVD) process, an atmospheric pressure chemical vapor deposition (APCVD) process, a metalorganic chemical vapor deposition (MOCVD) process, an atomic layer deposition (ALD) process or a physical vapor deposition (PVD) process, etc., and through the arrangement of the first protective layer 40, the PID effect can be effectively reduced and suppressed, and purposes of improving the power generation efficiency and reducing the cost of packaging cell modules, etc. can be achieved.

In this embodiment, the passivation layer 30 is an AlOₓ (X>0) layer; the first protective layer 40 is a SiOₓ (X>0) layer; and the second protective layer 50 is a SiNₓ (X>0) layer.

In this embodiment, the passivation layer 30 has a thickness greater than or equal to 3 nm and less than or equal to 20 nm; preferably, in one embodiment, the passivation layer 30 has a thickness between 7 nm and 15 nm, wherein according to different applications, the thickness may also be selected from intervals of 3 nm-7 nm, 7 nm-11 nm, 11 nm-15 nm, 15 nm-20 nm, and the like.

In this embodiment, the first protective layer 40 has a thickness less than or equal to that of the second protective layer 50; the first protective layer 40 has a thickness greater than or equal to 5 nm and less than or equal to 50 nm; preferably, in one embodiment, the first protective layer 40 has a thickness between 15 nm and 40 nm, wherein according to different applications, the thickness may also be selected from intervals of 5 nm-15 nm, 15 nm-26 nm, 26 nm-37 nm, 37 nm-50 nm and the like.

In this embodiment, the second protective layer 50 has a thickness greater than or equal to 50 nm and less than or equal to 100 nm; preferably, in one embodiment, the second protective layer has a thickness between 62.5 nm and 87.5 nm, wherein according to different applications, the thickness may also be selected from intervals of 50 nm-62.5 nm, 62.5 nm-75 nm, 75 nm-87.5 nm, 87.5 nm-100 nm, and the like.

It is further noted that in this embodiment, the passivation layer 30 has a refractive index greater than or equal to 1.50 and less than or equal to 1.70; preferably, in one embodiment, the passivation layer 30 has a refractive index between 1.55 and 1.65, wherein according to different applications, the refractive index may also be selected from intervals of 1.50-1.55, 1.55-1.6, 1.6-1.65, 1.65-1.70 and the like.

In this embodiment, the first protective layer 40 has a refractive index less than or equal to that of the second protective layer 50, and the first protective layer 40 has a refractive index greater than or equal to 1.46 and less than or equal to 1.90; preferably, in one embodiment, the first protective layer 40 has a refractive index between 1.57 and 1.79, wherein according to different applications, the refractive index may also be selected from intervals of 1.46-1.57, 1.57-1.68, 1.68-1.79, 1.79-1.90, and the like.

In this embodiment, the second protective layer 50 has a refractive index greater than or equal to 1.90 and less than or equal to 2.30; preferably, in one embodiment, the first protective layer 40 has a refractive index between 2.0 and 2.2, wherein according to different applications, the refractive index may also be selected from intervals of 1.9-2.0, 2.0-2.1, 2.1-2.2, 2.2-2.3 and the like.

Thus, by combining numerical ranges of the thicknesses and the refractive indexes of the passivation layer 30, the first protective layer 40, and the second protective layer 50 described above, a better technical effect of suppressing the PID effect can be achieved.

In this embodiment, the substrate 10 is illustrated with a doped P-type silicon substrate as an example, and as shown in FIG. 1, the front surface 12 of the substrate 10 is formed with a number of pyramidal or conical roughened structures, thus when the front surface 12 acts as a light incident surface, the roughened structures of the front surface 12 can reduce a probability that the incident light is lost by reflection from the front surface 12 to increase a chance that light rays are absorbed, which in turn improves a light-receiving area and increases a power generation efficiency.

With continued reference to FIG. 1, the semiconductor layer 20 is disposed on the front surface 12 and is in direct contact with the front surface 12, and in this embodiment, the semiconductor layer 20 combining with a doping type of the substrate 10 is illustrated with an N-type semiconductor layer as an example, thereby forming an emitter of the solar cell.

In this embodiment, the solar cell further includes a first front protective layer 60, wherein the semiconductor layer 20 and the first front protective layer 60 are sequentially disposed on the front surface 12 of the substrate 10 and are disposed in a direction away from the front surface 12, and the first front protective layer 60 may include a SiNₓ (X>0) material; and in this embodiment, the first front protective layer 60 is a SiNₓ (X>0) layer, and the first front protective layer 60 is in direct contact with the semiconductor layer 20.

In this embodiment, the solar cell 1 includes a plurality of upper electrodes 16 and a plurality of lower electrodes 18, wherein the upper electrodes 16 penetrate through the first front protective layer 60 and the semiconductor layer 20 and then are in contact with the substrate 10, and the lower electrodes 18 penetrate through the passivation layer 30, the first protective layer 40, and the second protective layer 50 and then are in contact with the substrate 10; in this embodiment, materials of the upper electrodes 16 and the lower electrodes 18 are illustrated with silver as an example; and in other embodiments, the upper electrodes 16 and the lower electrodes 18 may also be made of aluminum, or a composite of silver and aluminum, for example, and are not restricted to silver.

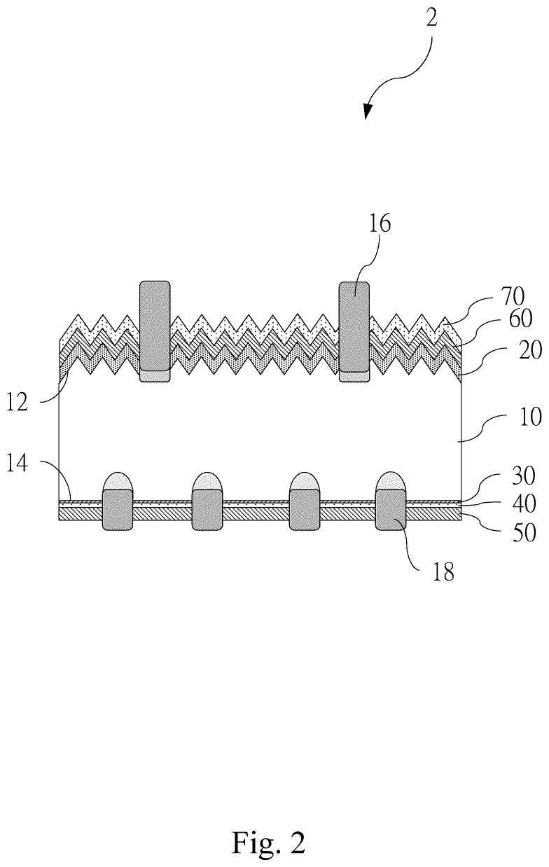

Referring to FIG. 2, a solar cell 2 of a second preferred embodiment of the present invention is shown and has a substantially same structure as the solar cell 1 of the first preferred embodiment described above, except that in the first preferred embodiment described above, the structure is illustrated with the semiconductor layer 20 and the first front protective layer 60 being disposed on the front surface 12 of the substrate 10 as an example; while in this embodiment, the solar cell 2 further includes a second front protective layer 70, and the semiconductor layer 20, the first front protective layer 60, and the second front protective layer 70 are sequentially disposed on the front surface 12 of the substrate 10 and are disposed in a direction away from the front surface 12, and the first front protective layer 60 is in contact with the second front protective layer 70, and the second front protective layer 70 includes a SiOₓ (X>0) material, thus achieving a better technical effect of suppressing the PID effect.

The second front protective layer 70 has a thickness greater than or equal to 10 nm and less than or equal to 100 nm; preferably, in one embodiment, the second front protective layer 70 has a thickness between 32.5 nm and 77.5 nm, wherein according to different applications, the thickness may also be selected from intervals of 10 nm-32.5 nm, 32.5 nm-55 nm, 55 nm-77.5 nm, 77.5 nm-100 nm, and the like.

The second front protective layer 70 has a refractive index greater than or equal to 1.46 and less than or equal to 1.70; preferably, in one embodiment, the second front protective layer 70 has a refractive index between 1.46 and 1.70, wherein according to different applications, the refractive index may also be selected from intervals of 1.46-1.52, 1.52-1.58, 1.58-1.64, 1.64-1.70, and the like.

Thus, through setting numerical ranges of the thicknesses and the refractive indexes of the second front protective layer 70 described above, a better technical effect of suppressing the PID effect can be achieved.

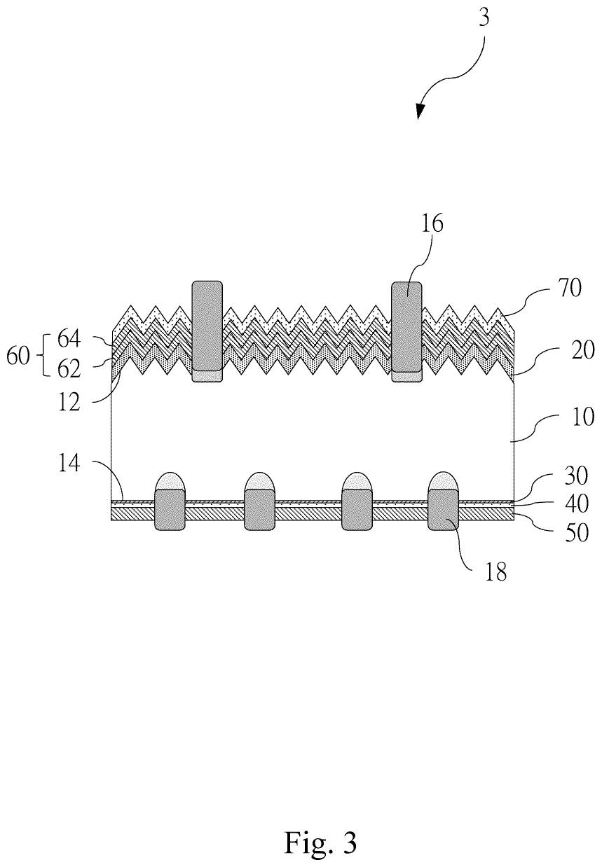

Referring to FIG. 3, a solar cell 3 of a third preferred embodiment of the present invention has a substantially same structure as the solar cell 2 of the second preferred embodiment described above, except that in the second preferred embodiment described above, the first front protective layer 60 is illustrated with a single-layer structure as an example; while in this embodiment, the first front protective layer 60 may also be a multi-layer structure, as shown in FIG. 3, the first front protective layer 60 includes a first silicon nitride structure 62 (SiNₓ, X>0) and a second silicon nitride structure 64 (SiNₓ, X>0) that are in contact with each other, the semiconductor layer 20, the first silicon nitride structure 62, the second silicon nitride structure 64, and the second front protective layer 70 are sequentially disposed in a direction away from the front surface 12 of the substrate 10, the first silicon nitride structure 62 has a refractive index greater than or equal to that of the second silicon nitride structure 64, and the second silicon nitride structure 64 has a refractive index greater than that of the second front protective layer.

The first silicon nitride structure 62 has a refractive index greater than or equal to 2.20 and less than or equal to 2.50; preferably, in one embodiment, the first silicon nitride structure 62 has a refractive index between 2.28 and 2.44, wherein according to different applications, the refractive index may also be selected from intervals of 2.2-2.28, 2.28-2.36, 2.36-2.44, 2.44-2.50, and the like.

The second silicon nitride structure 64 has a refractive index greater than or equal to 1.90 and less than or equal to 2.20; preferably, in one embodiment, the second silicon nitride structure 64 has a refractive index between 1.98 and 2.12, wherein according to different applications, the refractive index may also be selected from intervals of 1.9-1.98, 1.98-2.06, 2.06-2.12, 2.12-2.20, and the like.

The first silicon nitride structure 62 has a thickness greater than or equal to 10 nm and less than or equal to 50 nm; preferably, in one embodiment, the first silicon nitride structure 62 has a thickness between 20 nm and 40 nm, wherein according to different applications, the thickness may also be selected from intervals of 10 nm-20 nm, 20 nm-30 nm, 30 nm-40 nm, 40 nm-50 nm and the like.

The second silicon nitride structure 64 has a thickness greater than or equal to 10 nm and less than or equal to 50 nm; preferably, in one embodiment, the second silicon nitride structure 64 has a thickness between 20 nm and 40 nm, wherein according to different applications, the thickness may also be selected from intervals of 10 nm-20 nm, 20 nm-30 nm, 30 nm-40 nm, 40 nm-50 nm and the like.

Thus, through setting numerical ranges of the thicknesses and the refractive indexes of the first silicon nitride structure 62 and the second silicon nitride structure 64 described above, a better technical effect of suppressing the PID effect can be achieved.

The following is further illustrated by Comparative Examples 1-2 and Embodiment 1, and Comparative Examples 1-2 and Embodiment 1 show results of efficiency degradation percentages obtained by performing PID testing on solar cells with different structures for 96 hours in a manner consistent with the IEC62804 specification. The solar cell of Embodiment 1 is the solar cell 2 described in the second preferred embodiment above, and includes the substrate 10, the semiconductor layer 20, the passivation layer 30, the first protective layer 40, the second protective layer 50, the first front protective layer 60, and the second front protective layer 70, wherein, for example, the first front protective layer 60 in Embodiment 1 includes the first silicon nitride structure 62 and the second silicon nitride structure 64, and the thickness (nm) and the reflectivity (RI) of each of the passivation layer 30, the first protective layer 40, the second protective layer 50, the first front protective layer 60, and the second front protective layer 70 are recorded in Table 1. A difference between the solar cell structure of Comparative Example 1 and the solar cell structure of Embodiment 1 is that the first protective layer 40 is not disposed on the rear surface of the substrate in the solar cell structure of Comparative Example 1, and a difference between the solar cell structure of Comparative Example 2 and the solar cell structure of Embodiment 1 is that the second front protective layer 70 is not disposed on the front surface 12 of the substrate 10, and the first protective layer 40 is not disposed on the rear surface 14 of the substrate 10 in the solar cell structure of Comparative Example 2; that is to say, a SiOₓ layer is only disposed on the front surface 12 of the substrate 10 in the solar cell of Comparative Example 1, and no SiOₓ layer is disposed on the front surface 12 and the rear surface 14 of the substrate 10 in the solar cell of Comparative Example 2, whereas SiOₓ layers are disposed on both the front surface 12 and the rear surface 14 of the substrate 10 in the solar cell 2 of Embodiment 1. Referring to Table 2 below, it can be seen that efficiency degradation percentages of the solar cell of Comparative Examples 1-2 are greater than efficiency degradation percentages of the solar cell of Embodiment 1. That is to say, with the design in which the second front protective layer 70 is disposed on the front surface 12 of the substrate 10 and the first protective layer 40 is disposed on the rear surface 14 and the first protective layer 40 is disposed between the passivation layer 30 and the second protective layer 50, the purpose of significantly reducing or suppressing the PID effect can be achieved.

TABLE 1
Film thickness and reflectivity of Embodiment 1

| | Film | Reflectivity |
|---|---|---|
| Layer | thickness (nm) | (RI) |
| Second front protective layer 70 | 39 ± 3 | 1.53 ± 0.03 |
| Second silicon nitride structure 64 | 36 ± 3 | 2.12 ± 0.03 |
| First silicon nitride structure 62 | 14 ± 3 | 2.23 ± 0.03 |
| Passivation layer 30 | 10 ± 3 | 1.64 ± 0.03 |
| First protective layer 40 | 13 ± 3 | 1.48 ± 0.03 |
| Second protective layer 50 | 79 ± 3 | 2.14 ± 0.03 |

TABLE 2

| | | PID test |
|---|---|---|
| | | Efficiency |
| | | degradation |
| | Structure | (%) |
| Comparative | Front surface: semiconductor layer/first | 1.85 |
| Example 1 | front protective layer (SiNₓ) | |
| | Rear surface: passivation layer (AlOₓ)/ | |
| | second protective layer (SiNₓ) | |
| Comparative | Front surface: semiconductor layer/first | 1.48 |
| Example 2 | front protective layer (SiNₓ)/second front | |
| | protective layer (SiOₓ) | |
| | Rear surface: passivation layer | |
| | (AlOₓ)/second protective layer (SiNₓ) | |
| Embodiment 1 | Front surface: semiconductor layer/first | 1.06 |
| | front protective layer (SiNₓ)/second front | |
| | protective layer (SiOₓ) | |
| | Rear surface: passivation layer | |
| | (AlOₓ)/first protective layer | |
| | (SiOₓ)/second protective layer (SiNₓ) | |

In summary, according to the present invention, with the design in which the second front protective layer 70 is disposed on the front surface 12 of the substrate 10 and the first protective layer is disposed on the rear surface of the substrate and the first protective layer is disposed between the passivation layer and the second protective layer, the purposes of significantly reducing or suppressing the PID effect and further improving the power generation efficiency and lowering the cost of packaging cell modules, etc. can be achieved.

The above is only the feasible preferred embodiments of the present invention, and any equivalent changes made by the application of the description of and the claims of the present invention should be included within the patent scope of the present invention.

What is claimed is:

1. A solar cell, comprising:
a substrate having a front surface and a rear surface that are disposed oppositely;
a semiconductor layer disposed on the front surface;
a passivation layer comprising an AlOₓ (X>0) material;
a first protective layer comprising a SiOₓ (X>0) material; and
a second protective layer comprising a SiNₓ (X>0) material,
wherein the passivation layer, the first protective layer, and the second protective layer are disposed on the rear surface of the substrate and are sequentially disposed in a direction away from the rear surface.

2. The solar cell according to claim 1, wherein the passivation layer has a thickness greater than or equal to 3 nm and less than or equal to 20 nm.

3. The solar cell according to claim 1, wherein the first protective layer has a thickness greater than or equal to 5 nm and less than or equal to 50 nm.

4. The solar cell according to claim 1, wherein the second protective layer has a thickness greater than or equal to 50 nm and less than or equal to 100 nm.

5. The solar cell according to claim 1, wherein the first protective layer has a thickness less than or equal to that of the second protective layer.

6. The solar cell according to claim 1, wherein the passivation layer has a refractive index greater than or equal to 1.50 and less than or equal to 1.70.

7. The solar cell according to claim 1, wherein the first protective layer has a refractive index greater than or equal to 1.46 and less than or equal to 1.90.

8. The solar cell according to claim 1, wherein the second protective layer has a refractive index greater than or equal to 1.90 and less than or equal to 2.30.

9. The solar cell according to claim 1, wherein the first protective layer has a refractive index is less than or equal to that of the second protective layer.

10. The solar cell according to claim 1, comprising a first front protective layer and a second front protective layer, wherein the semiconductor layer, the first front protective layer, and the second front protective layer are disposed on the front surface of the substrate and sequentially disposed in a direction away from the front surface, the first front protective layer comprises a SiNₓ (X>0) material, and the second front protective layer comprises a SiOₓ (X>0) material.

11. The solar cell according to claim 10, wherein the second front protective layer has a thickness greater than or equal to 10 nm and less than or equal to 100 nm.

12. The solar cell according to claim 10, wherein the second front protective layer has a refractive index greater than or equal to 1.46 and less than or equal to 1.70.

13. The solar cell according to claim 10, wherein the first front protective layer is a multi-layer structure comprising a first silicon nitride structure and a second silicon nitride structure, the semiconductor layer, the first silicon nitride structure, the second silicon nitride structure, and the second front protective layer are sequentially disposed in a direction away from the front surface of the substrate, the first silicon nitride structure has a refractive index greater than or equal to that of the second silicon nitride structure, and the second silicon nitride structure has a refractive index greater than that of the second front protective layer.

14. The solar cell according to claim 13, wherein the first silicon nitride structure has a refractive index greater than or equal to 2.20 and less than or equal to 2.50, and the second silicon nitride structure has a refractive index greater than or equal to 1.90 and less than or equal to 2.20.

15. The solar cell according to claim 13, wherein the first silicon nitride structure has a thickness greater than or equal to 10 nm and less than or equal to 50 nm, and the second silicon nitride structure has a thickness greater than or equal to 10 nm and less than or equal to 50 nm.
